(19) United States
(12) Patent Application Publication
(10) Pub. No.: US 2009/0050909 A1
(43) Pub. Date: Feb. 26, 2009

(54) LIGHT-EMITTING DIODE APPARATUS AND MANUFACTURING METHOD THEREOF

(75) Inventors: Chao-Min CHEN, Taoyuan Hsien (TW); Shih-Peng Chen, Taoyuan Hsien (TW); Ching-Chuan Shiue, Taoyuan Hsien (TW); Huang-Kun Chen, Taoyuan Hsien (TW)

Correspondence Address: Muncy, Geissler, Olds & Lowe, PLLC, P.O. BOX 1364, FAIRFAX, VA, 22038-1364, US

(73) Assignee: DELTA ELECTRONICS, INC.

(21) Appl. No.: 12/178,975

(22) Filed: Jul. 24, 2008

(30) Foreign Application Priority Data
Aug. 20, 2007 (TW) 096130658

(51) Int. Cl. H01L 33/00; H01L 21/00

(52) U.S. Cl. 257/88; 438/29; 257/E33.001

(57) ABSTRACT

A light-emitting diode (LED) apparatus includes an epitaxial layer and an etching mask layer. The epitaxial layer has a first semiconductor layer, an active layer and a second semiconductor layer in sequence. The etching mask layer is disposed on the epitaxial layer and has a plurality of hollows. The second semiconductor layer includes a roughing structure.

### CROSS REFERENCE TO RELATED APPLICATIONS

This Non-provisional application claims priority under 35 U.S.C. §119(a) on Patent Application No(s). 096130658 filed in Taiwan, Republic of China on Aug. 20, 2007, the entire contents of which are hereby incorporated by reference.

### BACKGROUND OF THE INVENTION

1. Field of Invention

The invention relates to a light-emitting diode (LED) apparatus and a manufacturing method thereof.

2. Related Art

A light-emitting diode (LED) apparatus is a lighting apparatus made of semiconductor materials. The LED apparatus has the advantages of small size, low heat generated, low power consumption, no radiation, mercury-free, long lifetime, fast response speed and high reliability. With the continuous progress of the recent technology, the application range thereof covers the communication, customer electronics, vehicle, lighting and traffic sign.

However, the current LED apparatus still has the problems of poor light-emitting efficiency and low luminance.

To enhance the light-emitting efficiency, the surface structure or the fundamental structure of the LED can be modified. With reference to FIG. 1, a conventional LED apparatus 1 includes a substrate 11, a first semiconductor layer 12, an active layer 13, a second semiconductor layer 14, a transparent conductive layer 15 and a plurality of micro-tunnels 16. The micro-tunnels 16 are formed in the LED structure by dry etching or wet etching for enhancing the light-emitting efficiency.

As shown in FIG. 2, another conventional LED apparatus 2 includes a substrate 21, an epitaxial layer 22, a protective layer 23 and a plurality of electrodes 24. The protective layer 23 has a light-output surface, which has a surface roughing structure. The surface roughing structure can decrease the total reflection, thereby improving the light-emitting efficiency.

As shown in FIG. 3, another conventional LED apparatus 3 has an active layer 31 formed by the Reactive Ion Etching (RIE) process. Thus, the surface of the active layer 31 can have a sub-micron surface roughing structure with high aspect ratio, thereby increasing the light emitting efficiency thereof.

Although the above-mentioned LED apparatuses can enhance the light-emitting efficiency, their structures do not consider the refractive index matching between epitaxial layer and air. Thus, these LED apparatuses still have some reflection loss. In addition, the roughing surface can only achieve the micrometer level due to the limitation of semiconductor processes.

Therefore, there is a need to provide a LED apparatus and manufacturing method thereof, wherein there is a refractive index matching layer between epitaxial layer and air, thereby increasing the light-emitting efficiency.

### SUMMARY OF THE INVENTION

In view of the foregoing, an object of the present invention is to provide a LED apparatus and manufacturing method thereof, wherein there is a refractive index matching layer between the epitaxial layer and air, thereby increasing the light-emitting efficiency.

To achieve the above, the invention discloses a LED apparatus including an epitaxial layer and an etching mask layer. The epitaxial layer has a first semiconductor layer, an active layer and a second semiconductor layer in sequence. The etching mask layer is disposed on the epitaxial layer and has a plurality of hollows.

In addition, the invention also discloses a manufacturing method of a LED apparatus. The method includes the steps of: forming a first semiconductor layer on a substrate; forming an active layer on the first semiconductor layer; forming a second semiconductor layer on the active layer; removing a portion of the active layer and a portion of the second semiconductor layer so as to expose a portion of the first semiconductor layer; and forming an etching mask layer on the second semiconductor layer. The etching mask layer and the second semiconductor layer have a plurality of first hollows and a plurality of second hollows, respectively.

As mentioned above, the LED apparatus and manufacturing method of the present invention utilize the etching mask layer, which has a plurality of hollows, to avoid the total reflection loss caused by the difference between the refractive index of the epitaxial layer and that of air. Accordingly, the light-emitting efficiency can be further increased.

### BRIEF DESCRIPTION OF THE DRAWINGS

The invention will become more fully understood from the detailed description and accompanying drawings, which are given for illustration only, and thus are not limitative of the present invention, and wherein:

FIGS. 1 to 3 are schematic illustrations showing three kinds of conventional LED apparatuses;

FIG. 4 is a flow chart showing a manufacturing method of a LED apparatus according to a first embodiment of the invention;

FIGS. 5A to 5F are schematic illustrations showing the LED apparatus corresponding to the steps of FIG. 4;

FIG. 6 is a flow chart showing a manufacturing method of a LED apparatus according to a second embodiment of the invention;

FIGS. 7A to 7I are schematic illustrations showing the LED apparatus corresponding to the steps of FIG. 6;

FIG. 8 is a flow chart showing a manufacturing method of a LED apparatus according to a third embodiment of the invention;

FIGS. 9A to 9J are schematic illustrations showing the LED apparatus corresponding to the steps of FIG. 8;

FIG. 10 is a flow chart showing a manufacturing method of a LED apparatus according to a fourth embodiment of the invention;

FIGS. 11A to 11D are schematic illustrations showing the LED apparatus corresponding to the steps of FIG. 10;

FIG. 12 is a flow chart showing a manufacturing method of a LED apparatus according to a fifth embodiment of the invention;

FIGS. 13A to 13H are schematic illustrations showing the LED apparatus corresponding to the steps of FIG. 12;

FIG. 14 is a flow chart showing a manufacturing method of a LED apparatus according to a sixth embodiment of the invention; and

FIGS. 15A to 15I are schematic illustrations showing the LED apparatus corresponding to the steps of FIG. 14.

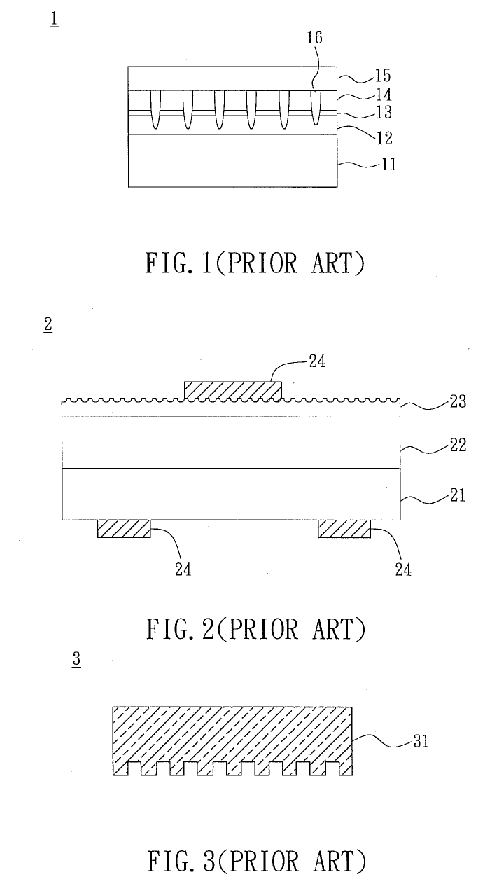

### DETAILED DESCRIPTION OF THE INVENTION

The present invention will be apparent from the following detailed description, which proceeds with reference to the accompanying drawings, wherein the same references relate to the same elements.

### First Embodiment

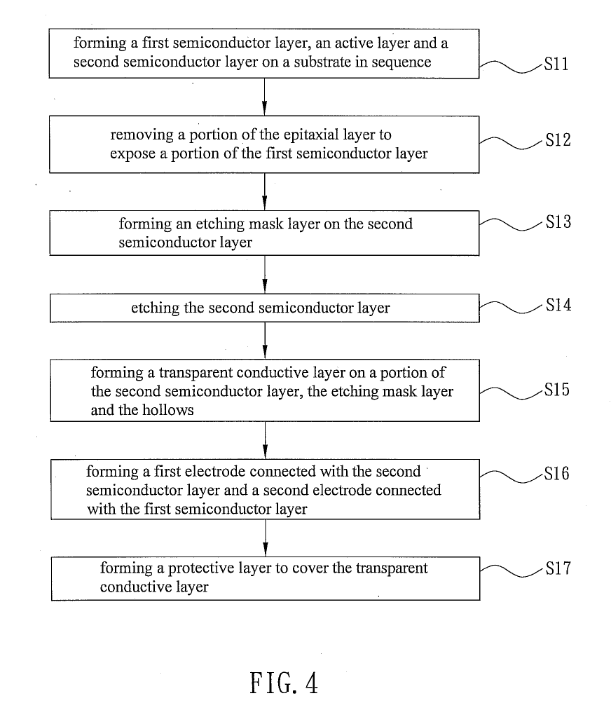

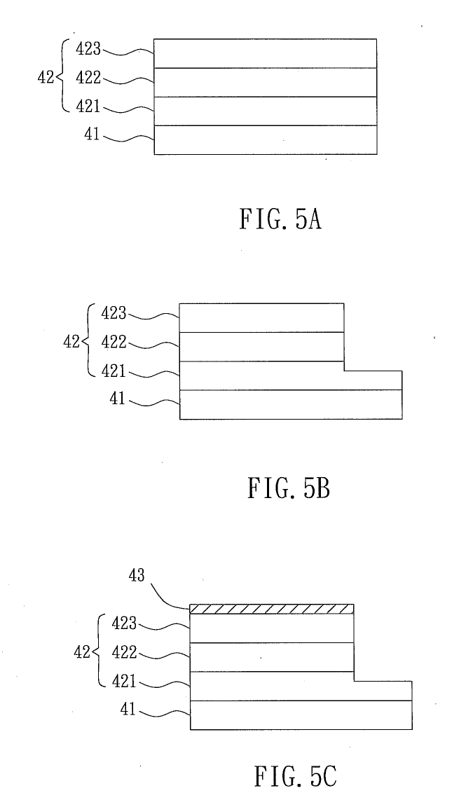

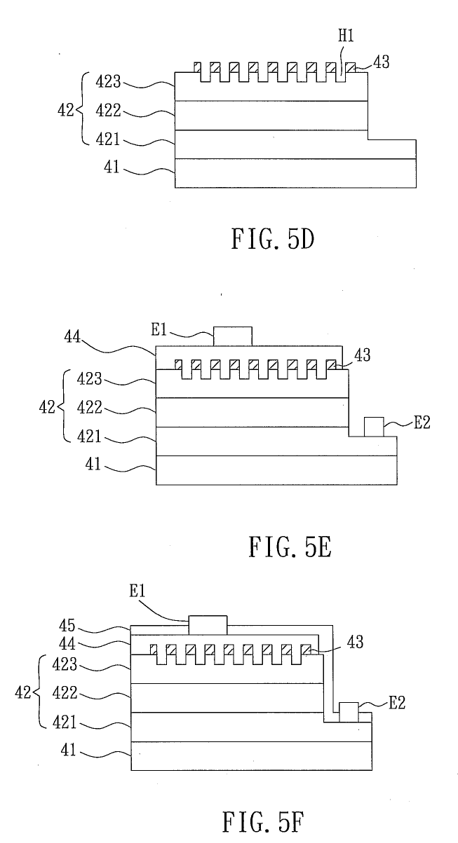

FIG. 4 is a flow chart showing a manufacturing method of a LED apparatus according to a first embodiment of the invention. With reference to FIG. 4, the manufacturing method includes the following steps S11 to S17. Illustrations will be made by referring to FIG. 4 in conjtmction with FIGS. 5A to 5F.

As shown in FIG. 5A, an epitaxial layer 42 is formed on a substrate 41 in step S11. The epitaxial layer 42 includes a first semiconductor layer 421, an active layer 422 and a second semiconductor layer 423. The first semiconductor layer 421 is formed on the substrate 41. The active layer 422 is formed on the first semiconductor layer 421. The second semiconductor layer 423 is formed on the active layer 422. In this embodiment, the first semiconductor layer 421 and the second semiconductor layer 423 can be respectively a P-type epitaxial layer and an N-type epitaxial layer, or respectively an N-type epitaxial layer and a P-type epitaxial layer.

As shown in FIG. 5B, in step S12 a portion of the epitaxial layer 42 is removed. In this embodiment, a portion of the first semiconductor layer 421, a portion of the active layer 422 and a portion of the second semiconductor layer 423 are etched away to expose a portion of the first semiconductor layer 421.

As shown in FIG. 5C, an etching mask layer 43 is formed on the second semiconductor layer 423 in step S13. In the embodiment, the etching mask layer 43 is formed on the second semiconductor layer 423 by, for example but not limited to, stacking, sintering, anodic aluminum oxidizing (AAO), nano-imprinting, hot pressing, transfer printing, etching or electron beam writer (E-beam writer) processing. The etching mask layer 43 has a plurality of hollows H1 as shown in FIG. 5D. The etching mask layer 43 has a refractive index ranging between that of air and that of the epitaxial layer 42. The material of the etching mask layer 43 can be photoresist, polymethylmethacrylate (PMMA) or anodic aluminum oxide.

In step S14, the second semiconductor layer 423 is etched. In this step S14, since the etching mask layer 43 is formed on the second semiconductor layer 423 as an etching mask for processing the second semiconductor layer 423 to have a roughing structure thereon. The roughing structure can be at least one nano-column, nano-hole, nano-point, nano-line, a nano-concave-convex structure, periodic holes structure or non-periodic holes. In addition, the roughing structure can be a geometric shape with non-planar side surfaces such as circular or polygonal.

In addition, the roughing structure of the second semiconductor layer 423, the etching mask layer 43 and the hollows H1 can be integrated as a non-planar roughing surface for efficiently outputting light, thereby increasing the light-emitting efficiency of the LED apparatus 4.

As shown in FIG. 5E, a transparent conductive layer 44 is formed on a portion of the second semiconductor layer 423, the etching mask layer 43 and the hollows H1 in step 15. The transparent conductive layer 44 has a refractive index ranging between that of the epitaxial layer 42 and that of air. The material of the transparent conductive layer 44 can be indium tin oxide (ITO), aluminum-doped zinc oxide (AZO), nickel/gold alloy (Ni/Au), zinc oxide (ZnO) or zinc gallium oxide.

In step S16, a first electrode E1 is formed to electrically connect with the second semiconductor layer 423, and a second electrode E2 is formed to electrically connect with the first semiconductor layer 421.

As shown in FIG. 5F, a protective layer 45 is formed to cover the transparent conductive layer 44, a portion of the first semiconductor layer 421, a portion of the active layer 422 and a portion of the second semiconductor layer 423 in step S17.

In this embodiment, the material of the protective layer 45 includes aluminum nitride (AlN), silicon oxide (SiO2), silicon nitride (Si3N4) or a plurality of mocro- or nano-particles. The refractive index of the protective layer 45 ranges between that of the epitaxial layer 42 and that of air. Herein, the protective layer 45 is an anti-reflection layer.

It is to be noted that the sequence of the above-mentioned steps can be changed according to the actual requirement. For example, the order of the steps S16 and S17 can be changed.

### Second Embodiment

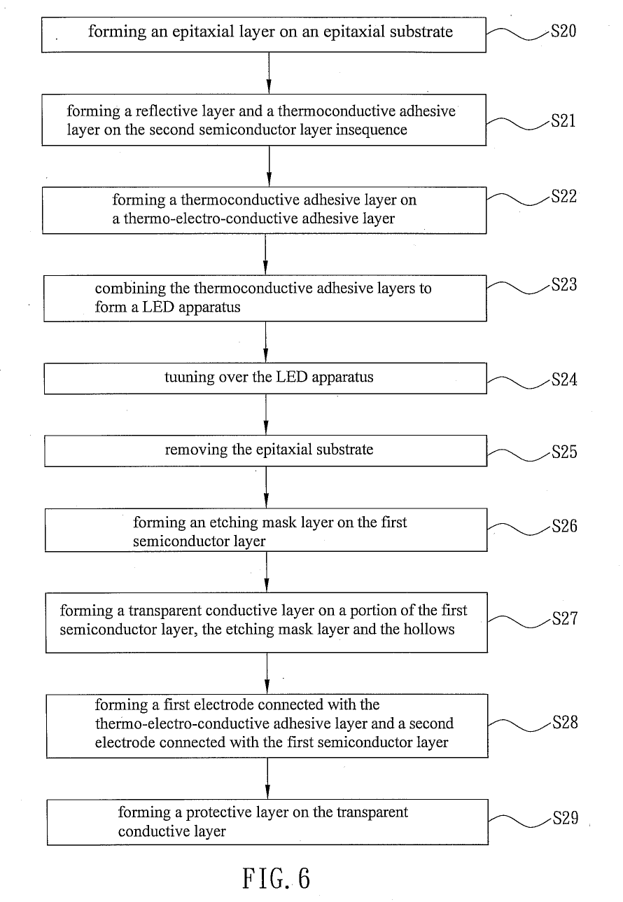

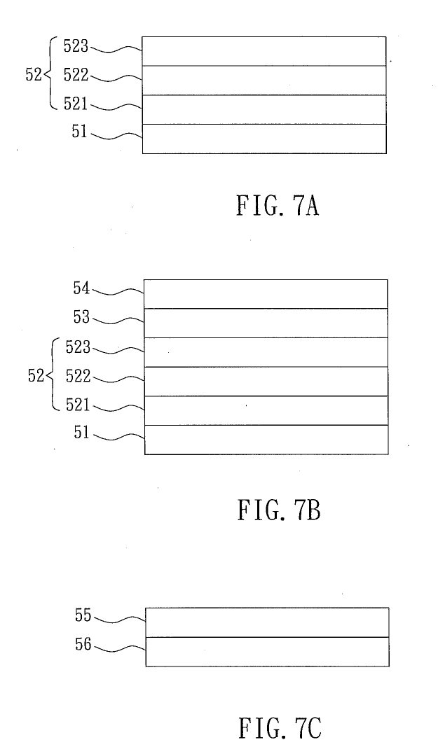

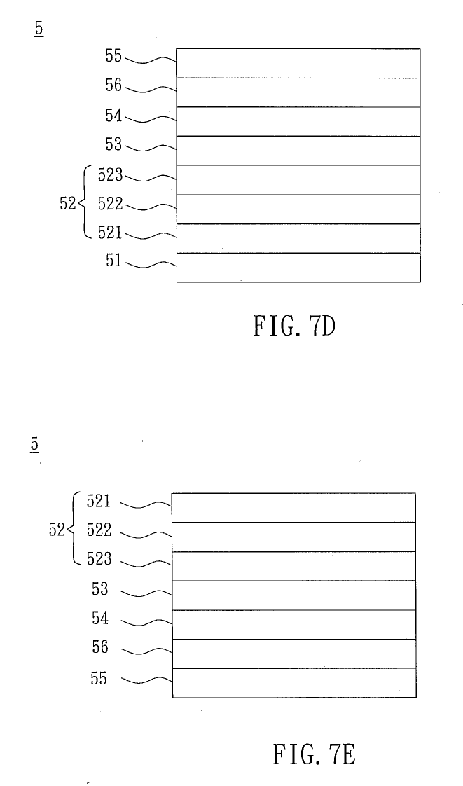

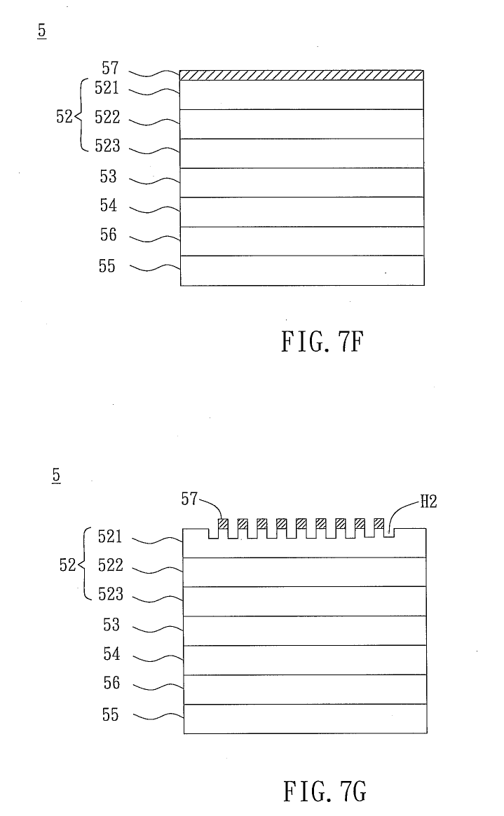

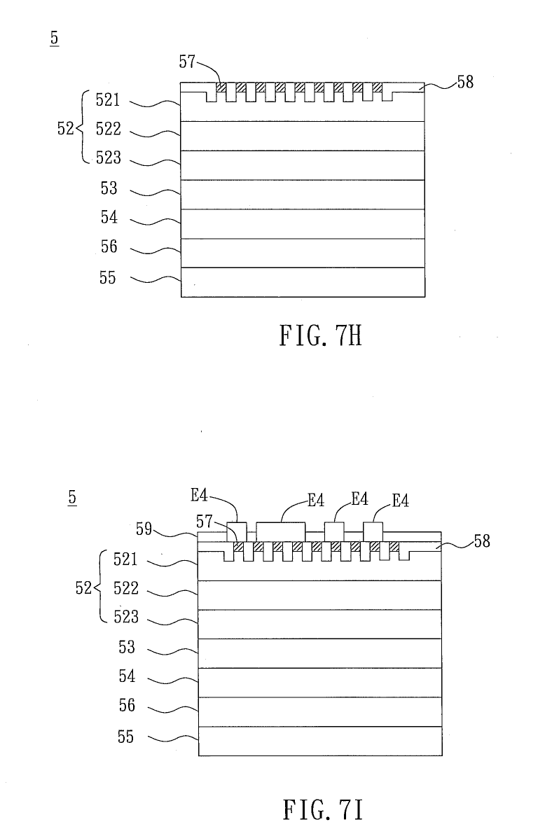

FIG. 6 is a flow chart showing a manufacturing method of a LED apparatus according to a second embodiment of the invention. With reference to FIG. 6, the manufacturing method includes the following steps S20 to S29. Illustrations will be made by referring to FIG. 6 in conjunction with FIGS. 7A to 7I.

As shown in FIG. 7A, an epitaxial layer 52 is formed on an epitaxial substrate 51 in step S20. The epitaxial layer 52 includes a first semiconductor layer 521, an active layer 522 and a second semiconductor layer 523. The first semiconductor layer 521 is formed on the epitaxial substrate 51. The active layer 522 is formed on the first semiconductor layer 521. The second semiconductor layer 523 is formed on the active layer 522. In this embodiment, the first semiconductor layer 521 and the second semiconductor layer 523 can be respectively a P-type epitaxial layer and an N-type epitaxial layer, or respectively an N-type epitaxial layer and a P-type epitaxial layer.

As shown in FIG. 7B, a reflective layer 53 is formed on the second semiconductor layer 523, and then a thermoconductive adhesive layer 54 is formed on the reflective layer 53 in step S21. The reflective layer 523 is an optical reflective device composed of dielectric films alternately stacked by high and low refractive index layers, a metal reflective layer, a metal dielectric reflective layer or an optical reflective device composed of micro- or nano-balls. The material of the reflective layer comprises platinum (Pt), gold (Au), silver (Ag), palladium (Pd), nickel (Ni), chromium (Cr), titanium (Ti), chromium/aluminum alloy (Cr/Al), nickel/aluminum alloy (Ni/Al), titanium/aluminum alloy (Ti/Al), titanium/silver alloy (Ti/Ag), chromium/platinum/aluminum alloy (Cr/Pt/Al) or a combination thereof. The material of the thermoconductive adhesive layer 54 can be a metal, an alloy, an electroconductive material, a non-electroconductive material or an organic material. Alternatively, the material of the thermoconductive adhesive layer 54 can be gold, a solder paste, a solder-silver paste, a silver paste or a combination thereof.

As shown in FIG. 7C, in step S22, a thermoconductive adhesive layer 56 is formed on a thermo-electro-conductive substrate 55. In this embodiment, the material of the thermo-electro-conductive substrate 55 can be silicon, gallium arsenide, gallium phosphide, silicon carbide, boron nitride, aluminum, aluminum nitride, copper or a combination thereof.

As shown in FIG. 7D, the step S23 is to combine the thermoconductive adhesive layers 54 and 56 so as to form a LED apparatus 5. As shown in FIG. 7E, the LED apparatus 5 is turned over in step S24, and the epitaxial substrate 51 is removed in step S25. To be noted, it is unnecessary to dispose both of the thermoconductive adhesive layers 54 and 56. In practice, either one or none of the thermoconductive adhesive layer 54 and 56 can be disposed.

As shown in FIG. 7F, an etching mask layer 57 is formed on the first semiconductor layer 521 in step S26. In the embodiment, the etching mask layer 57 is formed by, for example but not limited to, stacking, sintering, anodic aluminum oxidizing (AAO), nano-imprinting, hot pressing, transfer printing, etching or electron beam writer (E-beam writer) processing. The etching mask layer 57 has a plurality of hollows H2 as shown in FIG. 7G.

In the embodiment, the first semiconductor layer 521 is, for example but not limited to, etched to form a roughing structure, such as at least one nano-column, nano-hole, nano-point, nano-line, a nano-concave-convex structure, periodic holes or non-periodic holes. In addition, the roughing structure can be a geometric shape with non-planar side surfaces such as circular or polygonal.

In addition, the roughing structure of the first semiconductor layer 521, the etching mask layer 57 and the hollows H2 can be integrated as a non-planar roughing light-output surface, which can increase the light-emitting efficiency of the LED apparatus 5.

As shown in FIG. 7H, a transparent conductive layer 58 is formed on a portion of the first semiconductor layer 521, the etching mask layer 57 and the hollows H2 in step S27.

As shown in FIG. 7I, the thermo-electro-conductive substrate 55 serves as a first electrode, and a second electrode E4 is formed to electrically connect with the first semiconductor layer 521 in step S28.

In step S29, a protective layer 59 is formed to cover the transparent conductive layer 58 and the etching mask layer 57.

It is to be noted that the order of the above-mentioned steps can be changed according to the actual requirement.

### Third Embodiment

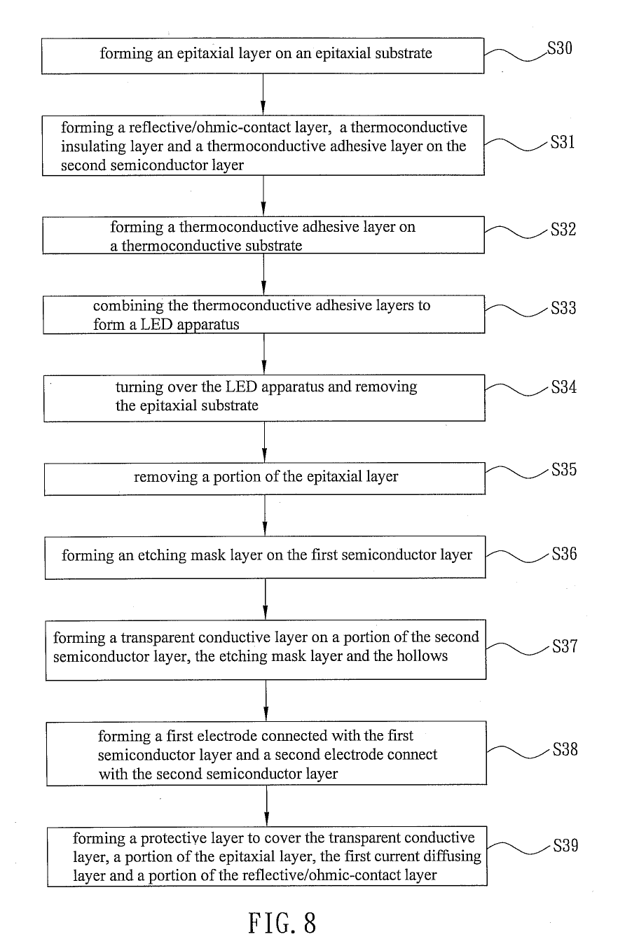

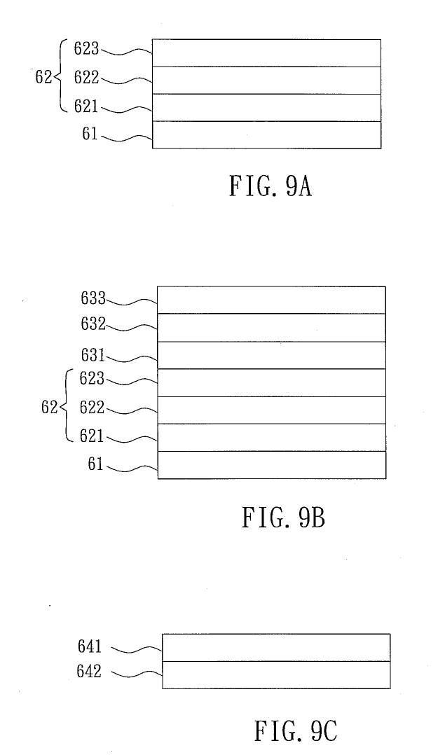

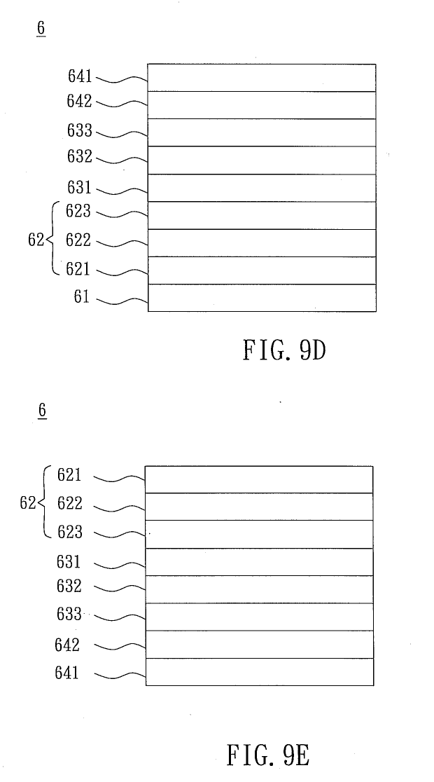

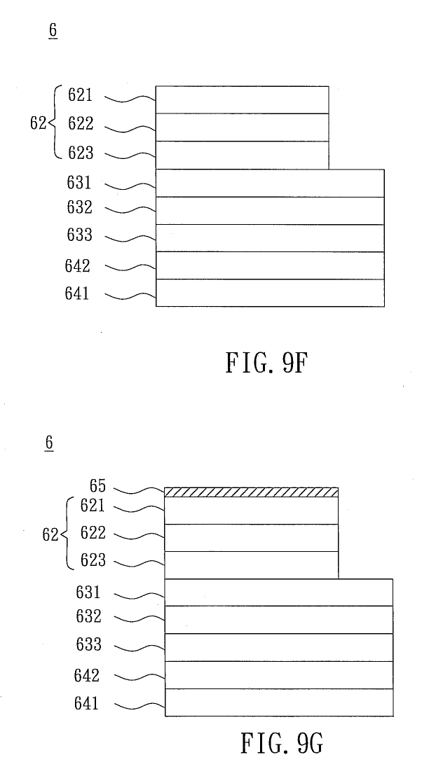

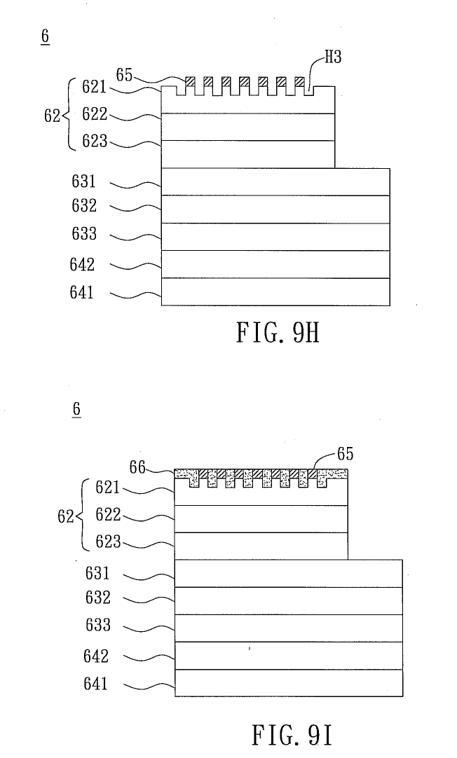

FIG. 8 is a flow chart showing a manufacturing method of a LED apparatus according to a third embodiment of the invention. With reference to FIG. 8, the manufacturing method includes the following steps S30 to S39. Illustrations will be made by referring to FIG. 8 in conjtmction with FIGS. 9A to 9J.

As shown in FIG. 9A, an epitaxial layer 62 is formed on an epitaxial substrate 61 in step S30. The epitaxial layer 62 includes a first semiconductor layer 621, an active layer 622 and a second semiconductor layer 623. The first semiconductor layer 621 is formed on the epitaxial substrate 61. The active layer 622 is formed on the first semiconductor layer 621. The second semiconductor layer 623 is formed on the active layer 622. In this embodiment, the first semiconductor layer 621 and the second semiconductor layer 623 can be respectively a P-type epitaxial layer and an N-type epitaxial layer, or respectively an N-type epitaxial layer and a P-type epitaxial layer.

As shown in FIG. 9B, a reflective ohmic-contact layer 631 is formed on the second semiconductor layer 623, a thermoconductive insulating layer 632 is formed on the reflective ohmic-contact layer 631, and then a thermoconductive adhesive layer 633 is formed on the thermoconductive insulating layer 632 in step S31. The reflective ohmic-contact layer 631 serves as a reflective layer and an ohmic-contact layer. In the embodiment, the refractive index of the thermoconductive insulating layer 632 ranges between that of the epitaxial layer 62 and that of air.

As shown in FIG. 9C, in step S32, a thermoconductive adhesive layer 642 is formed on a thermoconductive substrate 641. As shown in FIG. 9D, the thermoconductive adhesive layers 633 and 642 are combined in step S33 so as to form a LED apparatus 6. As shown in FIG. 9E, the LED apparatus 6 is turned over and the epitaxial substrate 61 is removed in step S34.

As shown in FIG. 9F, a portion of the epitaxial layer 62 is removed in step S35. In more details, a portion of the first semiconductor layer 621, a portion of the active layer 622 and a portion of the second semiconductor layer 623 are removed to expose a portion of the reflective ohmic-contact layer 631.

As shown in FIG. 9G, an etching mask layer 65 is formed on the first semiconductor layer 621 in step S36. In the embodiment, the etching mask layer 65 is formed by, for example but not limited to, stacking, sintering, anodic aluminum oxidizing (AAO), nano-imprinting, hot pressing, transfer printing, etching or electron beam writer (E-beam writer) processing. The etching mask layer 65 has a plurality of hollows H3 as shown in FIG. 9H.

In the embodiment, the first semiconductor layer 621 is, for example but not limited to, etched to form a roughing structure, such as at least one nano-column, nano-hole, nano-point, nano-line, a nano-concave-convex structure, periodic holes or non-periodic holes. In addition, the roughing structure can be a geometric shape with non-planar side surfaces such as circular or polygonal.

In addition, the roughing structure of the first semiconductor layer 621, the etching mask layer 65 and the hollows H3 can be integrated as a non-planar roughing light-output surface, which can increase the light-emitting efficiency of the LED apparatus.

As shown in FIG. 9I, a transparent conductive layer 66 is formed on a portion of the second semiconductor layer 623, the etching mask layer 65 and the hollows H3 in step S37.

As shown in FIG. 9J, a first electrode E5 is formed to electrically connect with the first semiconductor layer 621, and a second electrode E6 is formed to electrically connect with the second semiconductor layer 623 in step S38.

In step S39, a protective layer 67 is formed to cover the transparent conductive layer 66, a portion of the first semiconductor layer 621, a portion of the active layer 622, a portion of the second semiconductor layer 623 and a portion of the reflective ohmic-contact layer 631.

It is to be noted that the order of the above-mentioned steps can be changed according to the actual requirement.

### Fourth Embodiment

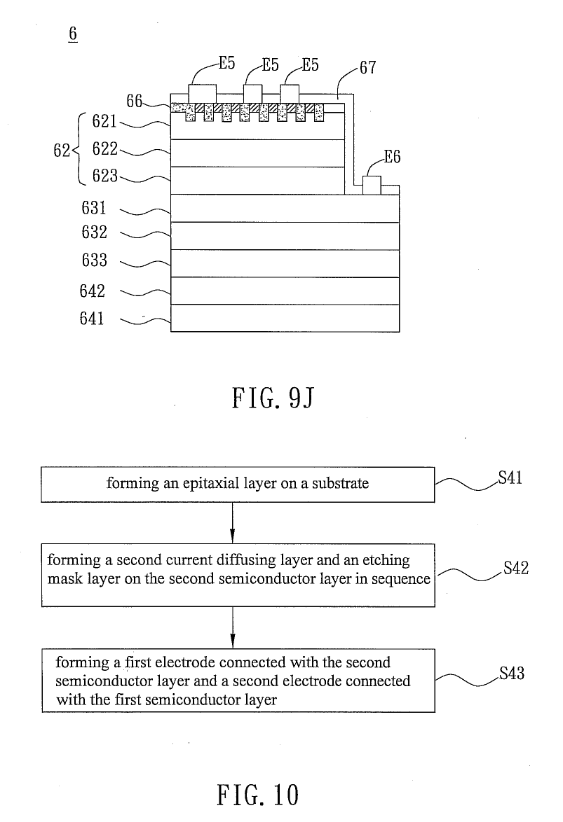

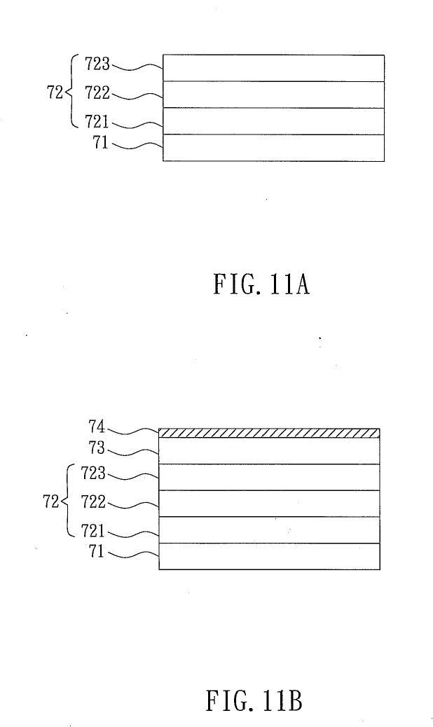

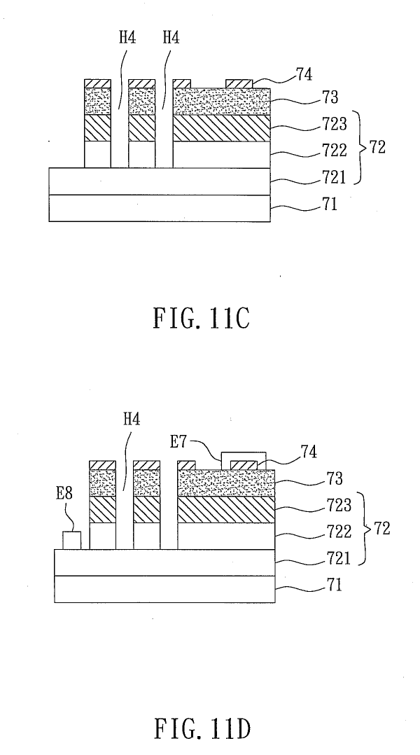

FIG. 10 is a flow chart showing a manufacturing method of a LED apparatus according to a fourth embodiment of the invention. With reference to FIG. 10, the manufacturing method includes the following steps S41 to S43. Illustrations will be made by referring to FIG. 10 in conjunction with FIGS. 11A to 11D.

As shown in FIG. 11A, an epitaxial layer 72 is formed on a substrate 71 in step S41. The epitaxial layer 72 includes a first semiconductor layer 721, an active layer 722 and a second semiconductor layer 723. The first semiconductor layer 721 is formed on the substrate 71. The active layer 722 is formed on the first semiconductor layer 721. The second semiconductor layer 723 is formed on the active layer 722. In this embodiment, the first semiconductor layer 721 and the second semiconductor layer 723 can be respectively a P-type epitaxial layer and an N-type epitaxial layer, or respectively an N-type epitaxial layer and a P-type epitaxial layer.

As shown in FIG. 11B, a second current diffusing layer 73 is formed on the second semiconductor layer 723, and then an etching mask layer 74 is formed on the second current diffusing layer 73 in step S42. In the embodiment, the etching mask layer 74 is formed on the second current diffusing layer 73 by, for example but not limited to, stacking, sintering, anodic aluminum oxidizing (AAO), nano-imprinting, hot pressing, transfer printing, etching or electron beam writer (E-beam writer) processing. The etching mask layer 74 has a plurality of hollows H4 as shown in FIG. 11C.

In the embodiment, the second current diffusing layer 73 is, for example but not limited to, etched to form the above-mentioned hollows H4. Thus, the above-mentioned hollows H4 are also formed on a portion of the second current diffusing layer 73.

In the embodiment, the second semiconductor layer 723 and the active layer 722 are, for example but not limited to, etched to form the above-mentioned hollows H4. Thus, the above-mentioned hollows H4 are also formed on a portion of the second current diffusing layer 73, a portion of the second semiconductor layer 723 and a portion of the active layer 722. To sum up, a etching step is performed on the etching mask layer 74 to remove a portion of the second current diffusing layer 73 and a portion of second semiconductor layer 723 and a portion of the active layer 722 to form the hollows H4 in the second current diffusing layer 73 and the second semiconductor layer 723 and the active layer 722.

As shown in FIG. 11D, a first electrode E7 is formed to electrically connect with the second semiconductor layer 723, and a second electrode E8 is formed to electrically connect with the first semiconductor layer 721 in step S43.

To be noted, the discontinuous structure of the LED apparatus shown in FIG. 11D is due to the viewing angle.

It is to be noted that the order of the above-mentioned steps can be changed according to the actual requirement.

### Fifth Embodiment

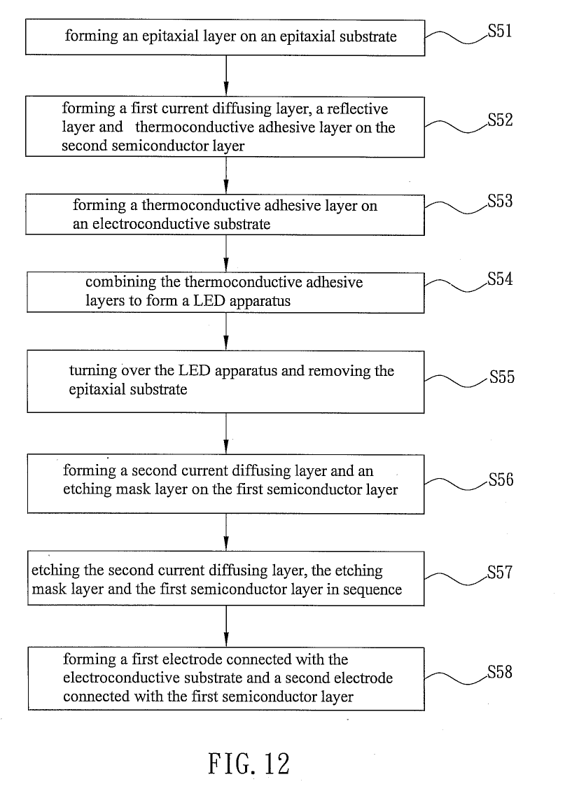

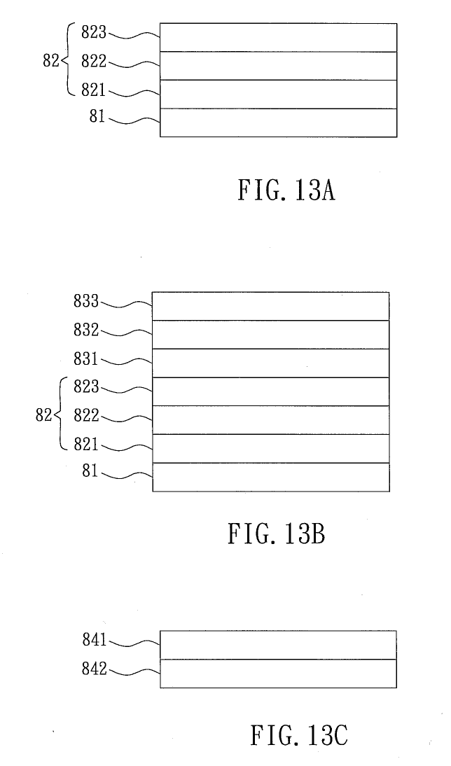

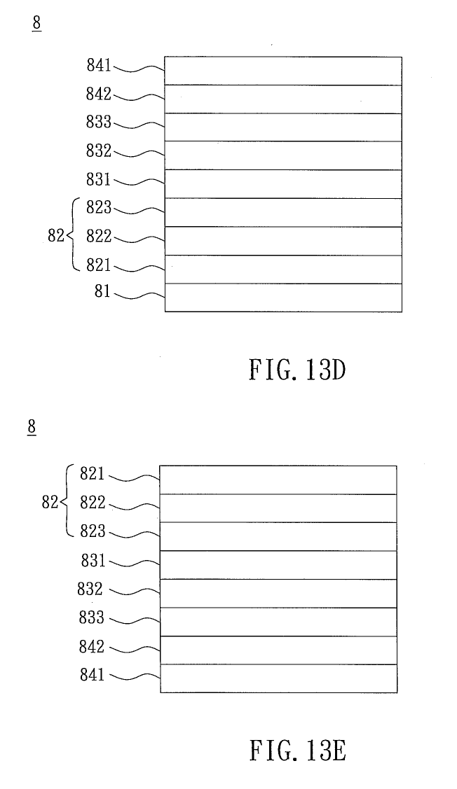

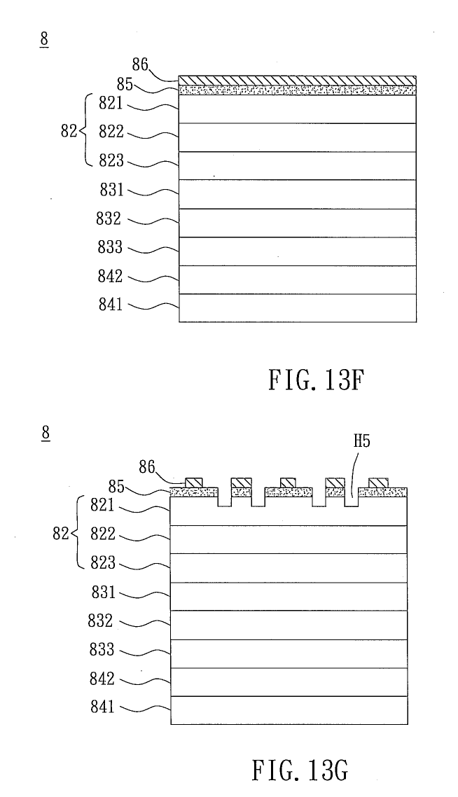

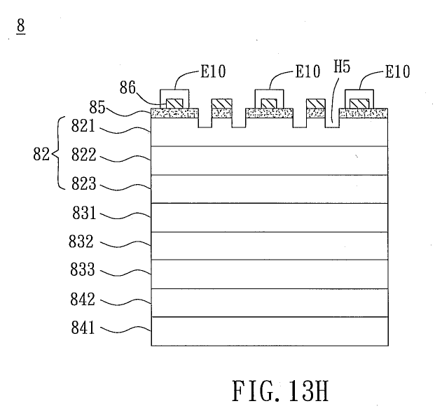

FIG. 12 is a flow chart showing a manufacturing method of a LED apparatus according to a fifth embodiment of the invention. With reference to FIG. 12, the manufacturing method includes the following steps S51 to S58. Illustrations will be made by referring to FIG. 12 in conjunction with FIGS. 13A to 13H.

As shown in FIG. 13A, an epitaxial layer 82 is formed on an epitaxial substrate 81 in step S51. The epitaxial layer 82 includes a first semiconductor layer 821, an active layer 822 and a second semiconductor layer 823. The first semiconductor layer 821 is formed on the epitaxial substrate 81. The active layer 822 is formed on the first semiconductor layer 821. The second semiconductor layer 823 is formed on the active layer 822. In this embodiment, the first semiconductor layer 821 and the second semiconductor layer 823 can be respectively a P-type epitaxial layer and an N-type epitaxial layer, or respectively an N-type epitaxial layer and a P-type epitaxial layer.

As shown in FIG. 13B, a first current diffusing layer 831 is formed on the second semiconductor layer 823, a reflective layer 832 is formed on the first current diffusing layer 831, and then a thermoconductive adhesive layer 833 is formed on the reflective layer 832 in step S52. As shown in FIG. 13C, a thermoconductive adhesive layer 842 is formed on an electroconductive substrate 841 in step S53. The material of the first current diffusing layer 831 can be indium tin oxide (ITO), aluminum-doped zinc oxide (AZO), zinc oxide (ZnO), nickel/aluminum alloy (Ni/Au) or antimony tin oxide (ATO).

As shown in FIG. 13D, the thermoconductive adhesive layers 833 and 842 are combined in step S54 so as to form a LED apparatus 8. As shown in FIG. 13E, the LED apparatus 8 is turned over and the epitaxial substrate 81 is removed in step S55.

As shown in FIG. 13F, a second current diffusing layer 85 is formed on the first semiconductor layer 821, and then an etching mask layer 86 is formed on the second current diffusing layer 85 in step S56. In the embodiment, the etching mask layer 86 is formed on the second current diffusing layer 85 by, for example but not limited to, stacking, sintering, anodic aluminum oxidizing (AAO), nano-imprinting, hot pressing, transfer printing, etching or electron beam writer (E-beam writer) processing. Then, in step S57, the second current diffusing layer 85, the etching mask layer 86 and the first semiconductor layer 821 are etched in sequence. In the embodiment, the etching mask layer 86 has a plurality of hollows H5 as shown in FIG. 13G.

In the embodiment, the second current diffusing layer 85 is, for example but not limited to, formed by etching. Thus, the above-mentioned hollows H5 are also formed on a portion of the second current diffusing layer 85.

In the embodiment, the second semiconductor layer 823 is, for example but not limited to, formed by etching. Thus, the second semiconductor layer 823 can be formed with a roughing structure, such as at least one nano-column, nano-hole, nano-point, nano-line, a nano-concave-convex structure, periodic holes or non-periodic holes. In addition, the roughing structure can be a geometric shape with non-planar side surfaces such as circular or polygonal.

As shown in FIG. 13H, the electroconductive substrate 841 serves as a first electrode, and a second electrode E10 is formed to electrically connect with the first semiconductor layer 821 in step S58. In the embodiment, the second electrode E10 covers a portion of the etching mask layer 86.

It is to be noted that the order of the above-mentioned steps can be changed according to the actual requirement.

### Sixth Embodiment

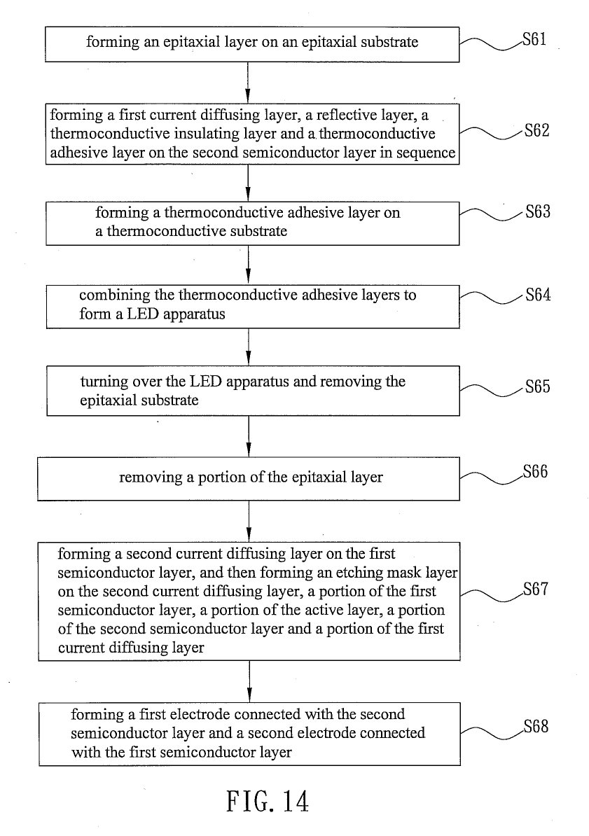

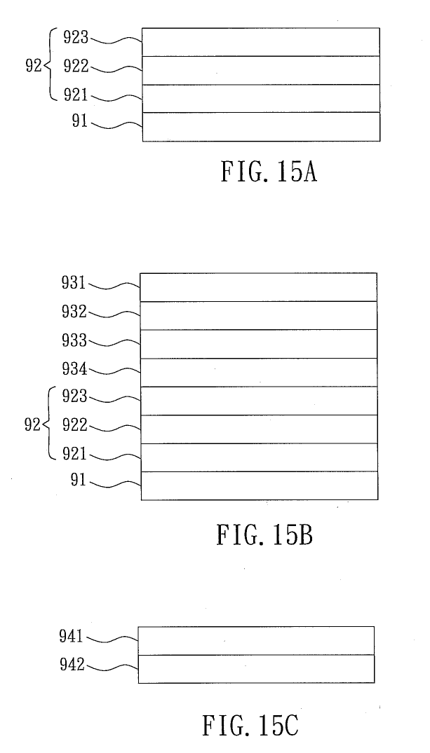

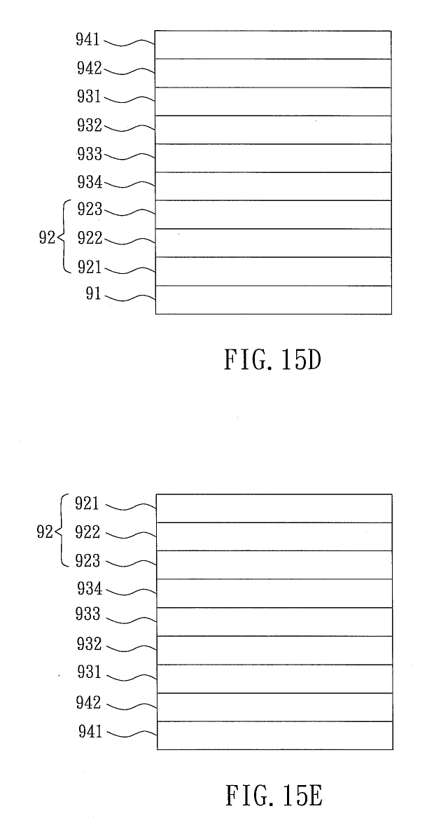

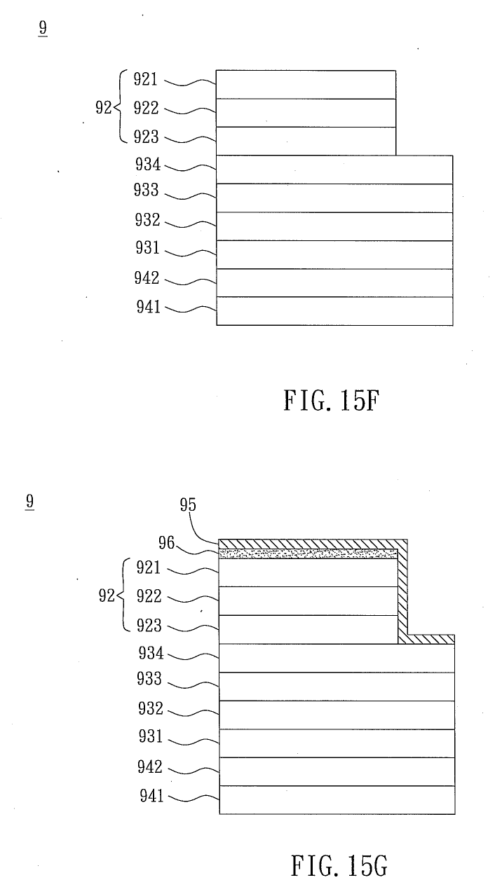

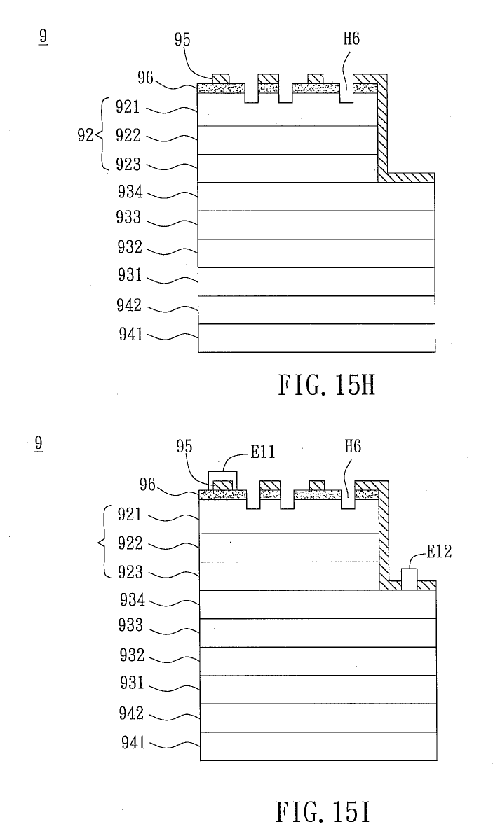

FIG. 14 is a flow chart showing a manufacturing method of a LED apparatus according to a sixth embodiment of the invention. With reference to FIG. 14, the manufacturing method includes the following steps S61 to S68. Illustrations will be made by referring to FIG. 14 in conjunction with FIGS. 15A to 15I.

As shown in FIG. 15A, an epitaxial layer 92 is formed on an epitaxial substrate 91 in step S61. The epitaxial layer 92 includes a first semiconductor layer 921, an active layer 922 and a second semiconductor layer 923. The first semiconductor layer 921 is formed on the epitaxial substrate 91. The active layer 922 is formed on the first semiconductor layer 921. The second semiconductor layer 923 is formed on the active layer 922. In this embodiment, the first semiconductor layer 921 and the second semiconductor layer 923 can be respectively a P-type epitaxial layer and an N-type epitaxial layer, or respectively an N-type epitaxial layer and a P-type epitaxial layer.

As shown in FIG. 15B, a first current diffusing layer 934 is formed on the second semiconductor layer 923, a reflective layer 933 is formed on the first current diffusing layer 934, a thermoconductive insulating layer 932 is formed on the reflective layer 933, and then a thermoconductive adhesive layer 931 is formed on the thermoconductive insulating layer 932 in step S62. As shown in FIG. 15C, a thermoconductive adhesive layer 942 is formed on a thermoconductive substrate 941 in step S63. The material of the first current diffusing layer 934 can be indium tin oxide (ITO), aluminum-doped zinc oxide (AZO), zinc oxide (ZnO), nickel/aluminum alloy (Ni/Au) or antimony tin oxide (ATO).

As shown in FIG. 15D, the thermoconductive adhesive layers 931 and 942 are combined in step S64 so as to form a LED apparatus 9. As shown in FIG. 15E, the LED apparatus 9 is turned over and the epitaxial substrate 91 is removed in step S65.

As shown in FIG. 15F, a portion of the epitaxial layer 92 is removed in step S66. In more details, a portion of the first semiconductor layer 921, a portion of the active layer 922 and a portion of the second semiconductor layer 923 are removed to expose a portion of the first current diffusing layer 934.

As shown in FIG. 15G, in step S67, a second current diffusing layer 96 is formed on the first semiconductor layer 921, and then an etching mask layer 95 is formed on the second current diffusing layer 96, a portion of the first semiconductor layer 921, a portion of the active layer 922, a portion of the second semiconductor layer 923 and a portion of the first current diffusing layer 934. In the embodiment, the etching mask layer 95 is formed by, for example but not limited to, stacking, sintering, anodic aluminum oxidizing (AAO), nano-imprinting, hot pressing, transfer printing, etching or electron beam writer (E-beam writer) processing. The etching mask layer 95 has a plurality of hollows H6 as shown in FIG. 15H.

In the embodiment, the second current diffusing layer 96 is, for example but not limited to, etched to form the above-mentioned hollows H6. Thus, the above-mentioned hollows H6 are also formed on a portion of the second current diffusing layer 96.

In the embodiment, the first semiconductor layer 921 is, for example but not limited to, etched to form a roughing structure, such as a nano-column, nano-hole, nano-point, nano-line, a nano-concave-convex structure, periodic holes or non-periodic holes. In addition, the roughing structure can be a geometric shape with non-planar side surfaces such as circular or polygonal.

As shown in FIG. 15I, a first electrode E12 is formed to electrically connect with the second semiconductor layer 923, and a second electrode E11 is formed to connect with the first semiconductor layer 921 in step S68. In the embodiment, the first electrode E12 and the second electrode E11 both cover a portion of the etching mask layer 95.

It is to be noted that the order of the above-mentioned steps can be changed according to the actual requirement.

In summary, the LED apparatus and manufacturing method of the invention utilize the etching mask layer, which has a plurality of hollows, to avoid the total reflection loss caused by the difference between the refractive index of the epitaxial layer and that of air. Accordingly, the light-emitting efficiency can be further increased. In addition, the LED apparatus of the invention has the advantages of uniform current diffusion, refractive index matching, good thermal stability and high light extracting efficiency.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode (LED) apparatus comprising:
an epitaxial layer having a first semiconductor layer, an active layer and a second semiconductor layer; and
an etching mask layer disposed on the epitaxial layer and having a plurality of hollows.

2. The LED apparatus according to claim 1, wherein a material of the etching mask layer comprises a photoresist, polymethylmethacrylate (PMMA) or anodic aluminum oxide, and the etching mask layer has a refractive index ranging between that of air and that of the epitaxial layer.

3. The LED apparatus according to claim 1, wherein one of the first and the second semiconductor layer is a P-type epitaxial layer and the other is an N-type epitaxial layer, and the second semiconductor layer comprises a roughing structure comprising at least one nano-column, nano-hole, nano-point, nano-line, a nano-concave-convex structure, periodic holes or non-periodic holes.

4. The LED apparatus according to claim 1, further comprising a substrate disposed opposite to the first semiconductor layer, wherein the substrate is an epitaxial substrate, a thermoconductive substrate, an electroconductive substrate or an insulating substrate.

5. The LED apparatus according to claim 4, wherein a material of the substrate comprises silicon, gallium arsenide, gallium phosphide, silicon carbide, boron nitride, aluminum, aluminum nitride, copper or a combination thereof.

6. The LED apparatus according to claim 4, further comprising a thermoconductive adhesive layer disposed between the substrate and the first semiconductor layer, wherein a material of the thermoconductive adhesive layer comprises gold, a solder paste, a solder-silver paste, a silver paste or a combination thereof, or a material of the thermoconductive adhesive layer comprises a pure metal, an alloy, an electroconductive material, a non-electroconductive material or an organic material.

7. The LED apparatus according to claim 4, further comprising a thermoconductive insulating layer disposed between the substrate and the first semiconductor layer, wherein a material of the thermoconductive insulating layer is aluminum nitride or silicon carbide.

8. The LED apparatus according to claim 4, further comprising a reflective layer disposed between the substrate and the first semiconductor layer, wherein the reflective layer is an optical reflective device composed of dielectric films alternately stacked by high and low refractive index layers, a metal reflective layer, a metal dielectric reflective layer or an optical reflective device composed of micro- or nano-balls, and the material of the reflective layer comprises platinum (Pt), gold (Au), silver (Ag), palladium (Pd), nickel (Ni), chromium (Cr), titanium (Ti), chromium/aluminum alloy (Cr/Al), nickel/aluminum alloy (Ni/Al), titanium/aluminum alloy (Ti/Al), titanium/silver alloy (Ti/Ag), chromium/platinum/aluminum alloy (Cr/Pt/Al) or a combination thereof.

9. The LED apparatus according to claim 4, further comprising a first current diffusing layer disposed between the substrate and the first semiconductor layer, wherein a material of the first current diffusing layer comprises indium tin oxide (ITO), aluminum-doped zinc oxide (AZO), zinc oxide (ZnO), nickel/aluminum alloy (Ni/Au) or antimony tin oxide (ATO).

10. The LED apparatus according to claim 1, further comprising a transparent conductive layer covering a portion of the second semiconductor layer, the etching mask layer and the hollows, wherein the transparent conductive layer has a refractive index ranging between that of the epitaxial layer and that of air, and a material of the transparent conductive layer comprises indium tin oxide (ITO), aluminum-doped zinc oxide (AZO), nickel/gold alloy (Ni/Au), zinc oxide (ZnO) or zinc gallium oxide.

11. The LED apparatus according to claim 10, further comprising a protective layer covering the transparent conductive layer, a portion of the first semiconductor layer, a portion of the active layer or a portion of the second semiconductor layer, wherein the protective layer is an anti-reflection layer, the protective layer has a refractive index ranging between that of the epitaxial layer and that of air, and a material of the protective layer comprises aluminum nitride (AlN), silicon oxide (SiO2), silicon nitride (Si3N4) or a plurality of micro- or nano-particles.

12. The LED apparatus according to claim 10, further comprising a protective layer covering the transparent conductive layer, wherein the protective layer is an anti-reflection layer, and the protective layer has a refractive index ranging between that of the epitaxial layer and that of air, and a material of the protective layer comprises aluminum nitride (AlN), silicon oxide (SiO2), silicon nitride (Si3N4) or a plurality of micro- or nano-particles.

13. The LED apparatus according to claim 1, further comprising a second current diffusing layer disposed between the etching mask layer and the second semiconductor layer, wherein the second current diffusing layer has a plurality of third hollows.

14. A manufacturing method of a light-emitting diode (LED) apparatus, comprising steps of:
forming a first semiconductor layer, an active layer and a second semiconductor layer on an epitaxial substrate in sequence; and
forming an etching mask layer on the second semiconductor layer, wherein the etching mask layer and the second semiconductor layer have a plurality of first hollows and a plurality of second hollows, respectively;

15. The method according to claim 14, further comprising steps of:
forming a transparent conductive layer on the etching mask layer, a portion of the second semiconductor layer, the first hollows and the second hollows; and
forming a protective layer on the transparent conductive layer.

16. The method according to claim 14, wherein the etching mask layer is formed on the second semiconductor layer by stacking, sintering, anodic aluminum oxidizing (AAO), nano-imprinting, hot pressing, transfer printing, etching or electron beam writer (E-beam writer) processing.

17. The method according to claim 15, wherein the second hollows and a portion of the second semiconductor layer form a roughing structure, wherein the roughing structure comprises a nano-concave-convex structure.

18. The method according to claim 15, further comprising a step of:
forming a thermoconductive insulating layer between the substrate and the first semiconductor layer, wherein a material of the thermoconductive insulating layer is aluminum nitride or silicon carbide.

19. The method according to claim 15, further comprising a step of:
forming a reflective layer between the substrate and the first semiconductor layer, wherein a material of the reflective layer comprises platinum (Pt), gold (Au), silver (Ag), palladium (Pd), nickel (Ni), chromium (Cr), titanium (Ti), chromium/aluminum alloy (Cr/Al), nickel/aluminum alloy (Ni/Al), titanium/aluminum alloy (Ti/Al), titanium/silver alloy (Ti/Ag), chromium/platinum/aluminum alloy (Cr/Pt/Al) or combinations thereof, and the reflective layer is an optical reflective device composed of dielectric films with different refraction indexes, a metal reflective layer, a metal dielectric reflective layer or an optical reflective device composed of micro- or nano-balls.

20. The method according to claim 15, further comprising a step of:
forming a thermoconductive adhesive layer between the substrate and the first semiconductor layer, wherein a material of the thermoconductive adhesive layer comprises gold, a solder paste, a solder-silver paste, a silver paste or combinations thereof, or a material of the thermoconductive adhesive layer comprises a metal, an alloy, an electroconductive material, a non-electroconductive material or an organic material.

21. The method according to claim 14, further comprising a step of:
forming a first current diffusing layer between the substrate and the first semiconductor layer, wherein a material of the current diffusing layer comprises indium tin oxide (ITO), aluminum-doped zinc oxide (AZO), zinc oxide (ZnO), nickel/aluminum alloy (Ni/Au) or antimony tin oxide (ATO).

22. The method according to claim 14, wherein after forming the second semiconductor layer, the method further comprises a step of:
forming a second current diffusing layer between the etching mask layer and the second semiconductor layer; or
forming a second current diffusing layer on the second semiconductor layer.

23. A manufacturing method of a light-emitting diode (LED) apparatus, comprising steps of:
forming a first semiconductor layer, an active layer and a second semiconductor layer on an epitaxial substrate in sequence;
forming a first current diffusing layer on the second semiconductor layer;
forming an etching mask layer on the first current diffusing layer, wherein the etching mask layer have a plurality of hollows; and
removing a portion of the first current diffusing layer and a portion of second semiconductor layer and a portion of the active layer to form the hollows in the first current diffusing layer and the second semiconductor layer and the active layer.

24. The method according to claim 23, wherein the etching mask layer is formed on the second semiconductor layer by stacking, sintering, anodic aluminum oxidizing (AAO), nano-imprinting, hot pressing, transfer printing, etching or electron beam writer (E-beam writer) processing.
